(19) United States
(12) Patent Application Publication
(10) Pub. No.: US 2026/0360443 A1
(43) Pub. Date: Nov. 12, 2026

(54) SYSTEM FOR PARALLEL READ OPERATIONS IN A MEMORY PLANE

(71) Applicant: Micron Technology, Inc., Boise, ID (US)

(72) Inventor: Tomoharu Tanaka, Yokohama (JP)

(73) Assignee: Micron Technology, Inc., Boise, ID (US)

(21) Appl. No.: 19/650,949

(22) Filed: Apr. 17, 2026

Related U.S. Application Data
(60) Provisional application No. 63/801,704, filed on May 7, 2025.

(51) Int. Cl. G11C 16/26; G11C 16/04; G11C 16/10

(52) U.S. Cl. CPC G11C 16/26; G11C 16/0483; G11C 16/10

(57) ABSTRACT

A memory device is provided. The device comprises a memory plane having a first sub-plane and a second sub-plane, a global bit line, a first dynamic latch device, a second dynamic latch device and control logic. The first sub-plane comprises a first group of memory cells. The second sub-plane comprises a second group of memory cells. The first dynamic latch device is controllably connected between the first group of memory cells and the global bit line. The second dynamic latch device is controllably connected between the second group of memory cells and the global bit line, the control logic is configured to cause one of the first or second dynamic latch device to communicate data sensed from the first or second group, respectively, to the global bit line while storing data sensed from the other one of the first or second group in the respective dynamic latch device.

### CROSS-REFERENCE TO RELATED APPLICATIONS

This application claims priority to U.S. Provisional Patent Application Ser. No. 63/801,704, filed May 7, 2025, entitled “SYSTEM FOR PARALLEL READ OPERATIONS IN A MEMORY PLANE”. The contents of these applications referenced in this section are hereby incorporated by reference in their entirety for all purposes.

### TECHNICAL FIELD

This disclosure relates to one or more systems for memory, including techniques for a memory device configuration in which parallel read operations can be performed in a single memory plane.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory cells in a memory device, in accordance with examples as disclosed herein.

FIG. 2D illustrates an example of a memory device including multiple blocks of memory cells in accordance with examples as disclosed herein.

FIG. 3 is a block diagram of an example apparatus for implementing one or more systems and for performing one or more methods described herein, in accordance with examples as disclosed herein.

FIG. 4 illustrates an example of a memory plane within a memory device in accordance with examples as disclosed herein.

FIG. 5 is an illustrative schematic of a first sub-plane of a memory plane and a first dynamic latch device in a memory device in accordance with examples as disclosed herein.

FIG. 6 illustrates the variations of multiple voltages applied to a memory plane over time, in accordance with examples as disclosed herein.

FIG. 7 illustrates the variations of multiple voltages applied to another memory plane over time, in accordance with examples as disclosed herein.

FIG. 8 illustrates a flowchart showing a data sensing method performed by the memory device in accordance with examples as disclosed herein.

### DETAILED DESCRIPTION

Aspects of the present disclosure are directed to a memory plane configuration in which the memory plane is divided into two sub-planes. Such memory plane configuration uses two dynamic latch devices to facilitate communication between the two sub-planes and a global bit line, such that the two sub-planes can be operated separately and in parallel. A memory device can include one or more memory planes. For some types of non-volatile memory devices (e.g., NAND flash memory device), each memory plane includes of a set of physical memory blocks (or simply “blocks”). Each block includes a set of sub-blocks. Each sub-block includes a string of memory cells. A memory cell is an electronic circuit that stores information. Depending on the cell type, a cell can store charges representing one or more bits of binary information and has various logic states that correlate to the number of bits being stored. The logic states can be represented by binary values, such as “0” and “1”, or combinations of such values.

A memory device includes memory cells arranged in a two-dimensional or a three-dimensional grid. Memory cells are formed onto a semiconductor (e.g., silicon) wafer in an array of columns or strings and rows. Each column of memory cells corresponds to a sub-block of memory cells that are connected to a same bit line. Each row of memory cells is connected to a same word line. The intersection of a bit line and word line constitutes the address of the memory cell. A block hereinafter refers to a unit of the memory device used to store data and can include many sub-blocks (e.g., many strings of memory cells each connected to a bit line). The sub-blocks in a memory block are typically connected to a global bit line for performing read and program operations. The global bit line is connected to a page buffer. One or more blocks can be grouped together to form separate partitions (e.g., memory planes or simply planes) of the memory device in order to allow concurrent operations to take place on each plane.

In some cases, random read IOPS (Input/Output Operations Per Second) may be used in reading operations of memory cells. Random read IOPS refers to a performance metric representing the number of discrete read operations performed by a memory device per second when accessing data stored at non-contiguous memory addresses. In contrast to sequential read operations, which involve retrieving data from consecutive addresses, random read operations require accessing different memory locations across the memory array, necessitating independent read cycles for each access.

For example, in a memory device comprising four memory planes—a first memory plane, a second memory plane, a third memory plane, and a fourth memory plane—a random read operation may be performed as follows: The controller issues a read command specifying an address in the first memory plane, triggering a sensing operation to retrieve the corresponding data. Subsequently or asynchronously, the controller issues another read command for a non-contiguous address located in the third memory plane, requiring a separate sensing operation. This process continues as the controller executes read operations targeting scattered locations across the multiple memory planes. The total number of such discrete read operations that can be completed within one second defines the random read IOPS of the memory device.

An iWL (independent Word Line) feature may be used to enhance random read IOPS. For example, the iWL feature allows multiple independent read operations to occur (one operation per memory plane) in parallel, thereby enabling read operations to be performed in parallel (e.g., multiple memory cells in different memory planes can be read in parallel). Thus, by using iWL, read operations can have faster data sensing and reduced read latency. In turn, iWL can improve the overall memory performance.

The iWL feature, however, requires increasing the number of memory planes within a die to enable parallel reading operations because all memory blocks in a memory plane share a same global bit line. As a result, the number of random read parallelism is limited by the number of memory planes in a die. However, the number of memory planes within a die is subject to physical constraints. The increasing number of memory planes within a die leads to a situation where the numbers of the page buffers and peripheral circuits also need to be increased. This results in an increase in die size and manufacturing cost, negatively impacting cost-efficiency and power consumption. Therefore, while increasing the plane count can improve random read performance by increasing parallel operations, the improvement is at the cost of increasing die size and power consumption. Accordingly, the improvement of parallelism should be balanced against die size limitations and economic feasibility to maintain an optimal memory design.

Aspects of the present disclosure address the above and other deficiencies by dividing each memory plane into two sub-planes. For example, a plane can be divided into top and bottom sub-planes, such that the operations performed on each sub-plane can be processed independently or in parallel. In addition, dynamic latch devices are used to enable further parallel read operations. In one example, a first dynamic latch device is controllably connected between a first sub-plane (e.g., top sub-plane) and the global bit line, and a second dynamic latch device is controllably connected between a second sub-plane (e.g., bottom sub-plane) and the global bit line. The two dynamic latch devices can establish communication between the global bit line and a respective sub-plane. In this manner, more sub-planes can operate independently without increasing the number of memory planes, thereby enhancing random read performance.

For example, if a selected memory cell (e.g., a first memory cell) in the top sub-plane undergoes a data sensing operation, the first dynamic latch device can be activated to allow communication between the selected memory cell in the top sub-plane and the global bit line. The page buffer then senses the data from the selected memory cell through the global bit line. Meanwhile, the second dynamic latch device is inactive such that the memory cells in the bottom sub-plane cannot communicate with the global bit line. However, the memory cell needs to be sensed later in the bottom sub-plane (e.g., a second memory cell) can be pre-charged and the data sensed from the second memory cell can be temporarily stored in the second dynamic latch device. Once the second dynamic latch device is activated (and the first dynamic latch device is deactivated), the page buffer can obtain the sensed data from the second dynamic latch device via the global bit line.

In some examples, the first sub-plane (e.g., top sub-plane) and the second sub-plane (e.g., bottom sub-plane) are coupled to different sets of word lines, and data stored in the two sub-planes can be sensed independently. For example, the memory cells in the first sub-plane are coupled to a first set of local word lines, while the memory cells in the second sub-plane are coupled to a second set of local word lines. During data sensing operations, a specific voltage can be applied to the first set of local word lines to sense data stored in the selected memory cells in the first sub-plane, while a different voltage is applied to the second set of local word lines to sense data stored in the selected memory cells in the second sub-plane. This configuration enables independent operation of the selected memory cells in different sub-planes, preventing interference between them.

In some examples, the sensed data represents one or more logical states of one or more selected memory cells. For example, a memory array forms a part of a TLC (tri-level cell) memory device. A TLC memory device has 8 logic levels (denoted as L0-L7). Accordingly, the selected memory cells in the first or second sub-plane may require a maximum 7 data sensing operations to determine all three logical states of the selected memory cells. In each data sensing operation, the selected memory cells are applied with a different word line voltage (e.g., R1-R7) to determine its logical states. After one or more data sensing operations (e.g., up to seven), which means up to 7 different word line voltages are applied to the selected memory cells, the page buffer can determine the logic level (e.g., L0-L7) of the first memory cell.

Advantages of the technologies disclosed herein include, but are not limited to, increasing the number of parallel read operations that can be performed without increasing the number of memory planes. The increasing of the number of parallel read operations are enabled by using dynamic latch devices. As a result, a memory plane can be divided into a plurality of sub-planes (e.g., a top sub-plane and a bottom sub-plane). Parallel read operations can be performed with respect to memory cells in the plurality of sub-planes, while the dynamic latch device can be used to temporarily store the data sensed from the memory cells. The transferring of the sensed data from the memory cells in multiple sub-planes can be performed serially to the global bit line. Accordingly, the random read IPOS can be improved without increasing the number of memory planes, and in turn without having to adding more page buffers and peripheral circuits. Furthermore, since each sub-plane can be operated separately, more bits can be read in parallel, improving overall memory performance during random read operations. The power consumption increase due to the parallel random read operations can also be limited or minimized.

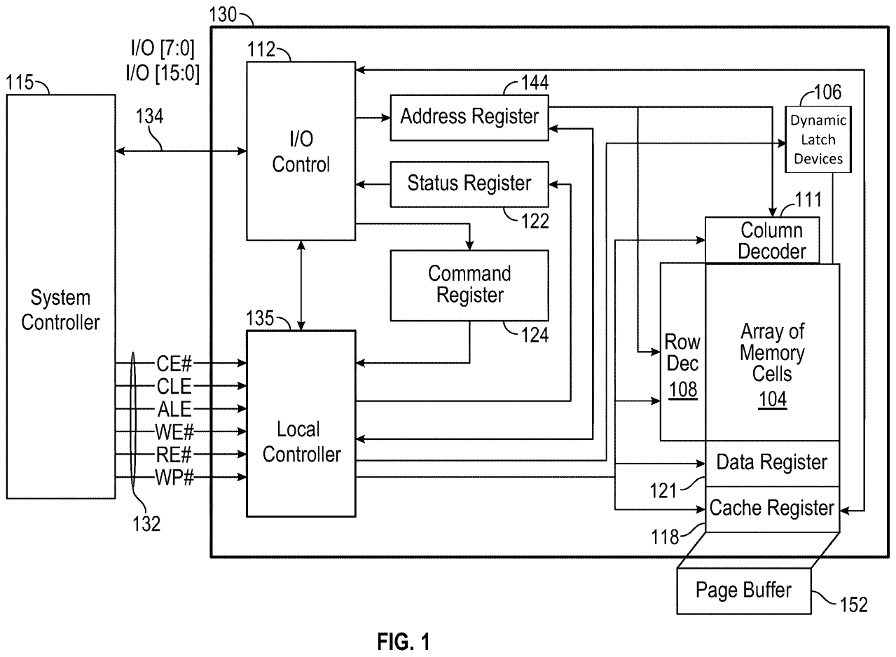

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115. For example, the local controller 135, on its own or in response to a command provided by external system controller 115, is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses. In this disclosure, a controller (e.g., the local controller 135 or the system controller) is also referred to as the control logic.

In some examples, local controller 135 communicates with the external system controller 115, which may be a host controller (e.g., an UFS or eMMC controller, or a CPU communicating with local controller 135) located in a host system or a memory system controller located in a memory system. In some examples, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some examples, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some examples, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

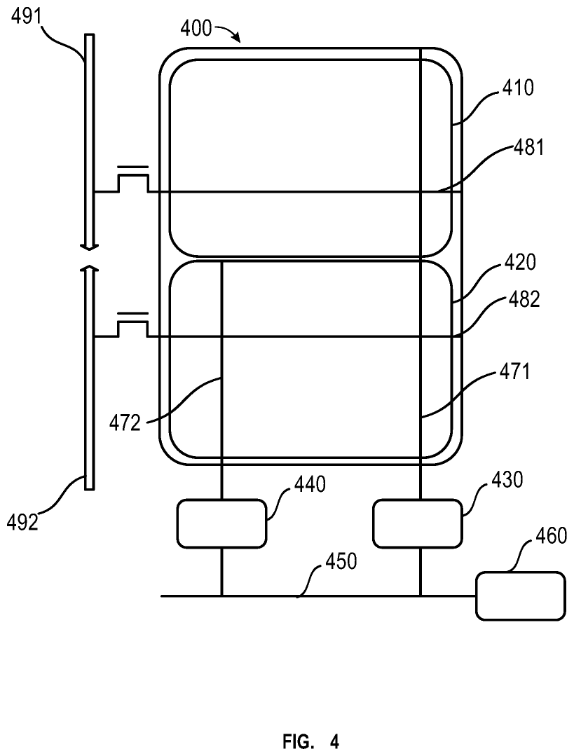

FIG. 1 also illustrates that dynamic latch devices 106 can be disposed with the array of memory cells 104. As described in more details below, in some examples, dynamic latch devices 106 are connected to the sub-blocks of memory blocks in the array of memory cells 104. Dynamic latch devices 106 are also connected to a global bit line (shown in FIG. 4). The global bit line can be connected to a page buffer 152.

With continued reference to FIG. 1, memory device 130 receives various control signals via local controller 135 from system controller 115 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 144. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

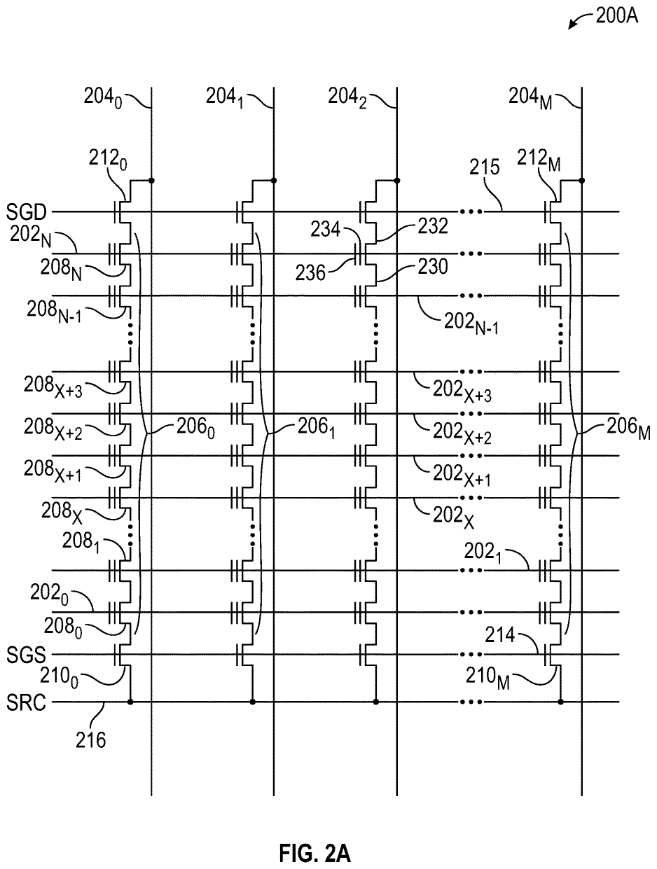

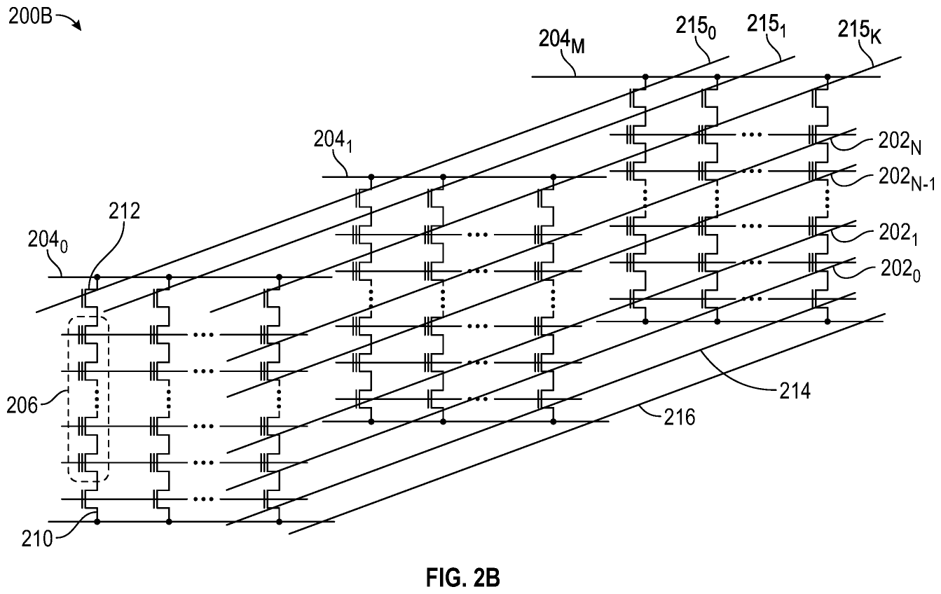

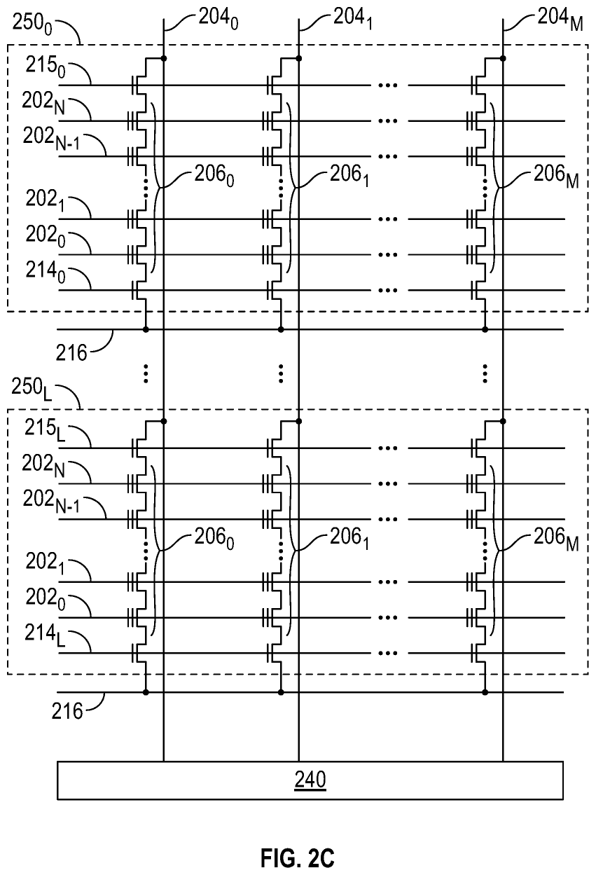

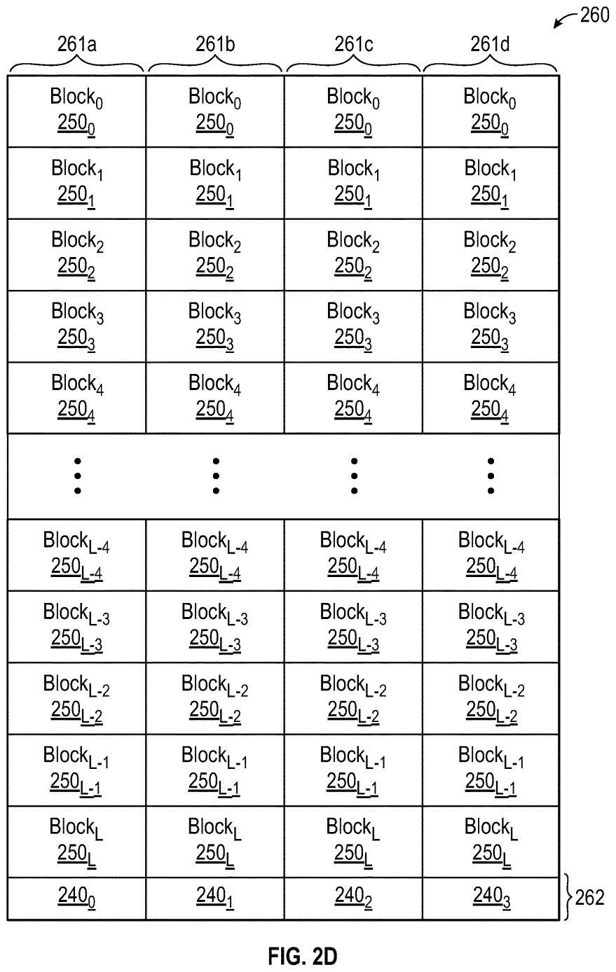

FIG. 2A-2B are example schematics of portions of an array of memory cells 200A, such as a NAND memory array. Array of memory cells 200A may be an example of memory array 104 of a memory device 130 as described with reference to FIG. 1 according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some examples, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some examples, each sub-block or string of memory cells has a separate select line 214 from other sub-blocks or strings. In some examples, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204. In one example, buffer portion 240 can be a part of page buffer 152. As described below, multiple buffer portions 240 may collectively form a page buffer 152.

FIG. 2D is a block schematic of a portion of an example array of memory cells 260. Array of memory cells 260 can be used as array 104 in a memory device 130. The array of memory cells 260 is depicted as having four memory planes 261 (e.g., memory planes 261a-261d). Each of the memory planes 261 may refer to a group of memory blocks of memory cells 250. Each memory plane 261 can be in communication with a respective buffer portion 240, which can collectively form a page buffer 262. Page buffer 262 may be used to implement page buffer 152 shown in FIG. 1. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

In some cases, concurrent operations may be performed on different planes. For example, concurrent operations may be performed on memory cells within different blocks 250 so long as the different blocks 250 are in different planes 261. In some cases, an individual memory block 250 may be referred to as a physical block, and a virtual block may refer to a group of blocks 250 within which concurrent operations may occur. For example, concurrent operations may be performed on four blocks of 250₀ that are within planes 261a, 261b, 261c, and 261d, respectively, and the four blocks of 250₀ may be collectively referred to as a virtual block. In some cases, a virtual block may include blocks from different memory devices. In some cases, the physical blocks within a virtual block may have the same block address within their respective planes. In some cases, performing concurrent operations in different planes 261 may be subject to one or more restrictions, such as concurrent operations being performed on memory cells within different pages that have the same page address within their respective planes 261 (e.g., related to command decoding, page address decoding circuitry, or other circuitry being shared across planes 261).

In some cases, a block 250 may include memory cells organized into rows (pages) and columns (e.g., strings, not shown). For example, memory cells in a same page may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page may, in some cases, not be updated until the entire block that includes the page has been erased.

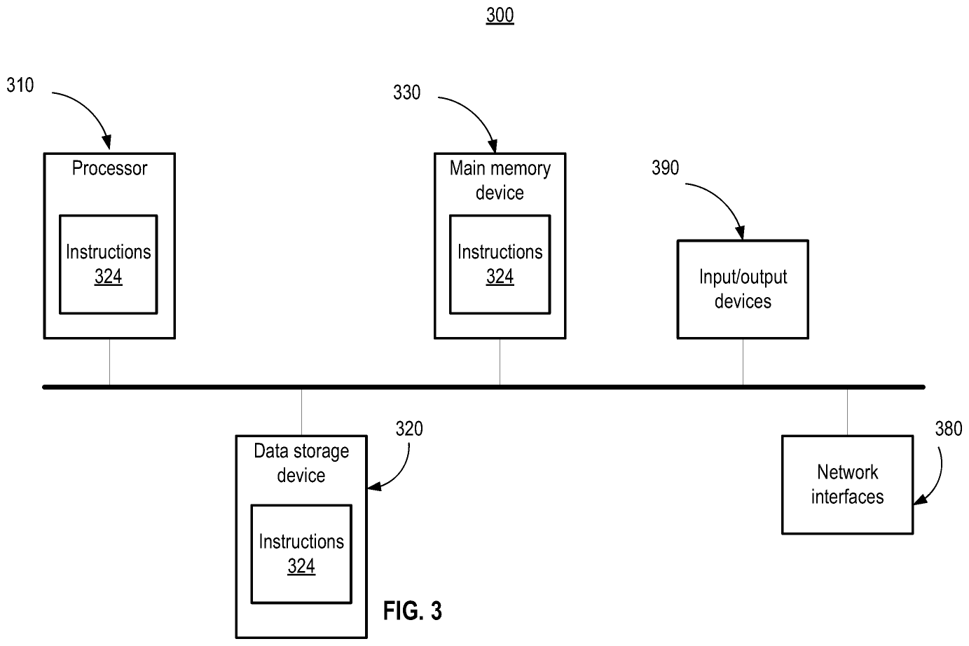

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-8, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some examples, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIGS. 1-8 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-8. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

FIG. 4 illustrates an example of a memory plane 400 within a memory device in accordance with examples as disclosed herein. Memory plane 400 can be any of the memory plane 261 as described above. In one example, memory plane 400 can include a first sub-plane 410 and a second sub-plane 420. As shown in FIG. 4, the first sub-plane 410 may be positioned at the upper portion of the memory plane 400 (hereafter referred to as the “top sub-plane”), while the second sub-plane 420 may be positioned at the lower portion of the memory plane 400 (hereafter referred to as the “bottom sub-plane”). It is understood that the top and bottom portions are for differentiating the sub-planes and thus can be interchanged. For example, in FIG. 4, the top sub-plane can be termed the bottom sub-plane, and vice versa. Both sub-planes may include multiple memory blocks. The number of memory blocks in each sub-plane may be the same or different. Thus, the memory plane is divided into two groups of memory cells: a first group of memory cells in the first sub-plane 410 and a second group of memory cells in the second sub-plane 420.

As described above, a memory device includes a global bit line 450. During a program operation, a selected memory cell can be programmed by applying a specific voltage to the global bit line 450 and applying a particular word line voltage to the word line connected to the selected memory cell. During a data sensing operation, the global bit line voltage can be modulated by a selected memory cell to retrieve stored data. The global bit line 450 is connected to both the top and bottom sub-planes 410 and 420, thereby linking all local bit lines within each sub-plane. When the global bit line 450 is configured to communicate with the top sub-plane 410, it can facilitate programming data to, and/or sensing data from, selected memory cells in the top sub-plane 410. Similarly, when configured to communicate with the bottom sub-plane 420, it can facilitate programming data to, and/or sensing data from, selected memory cells in the bottom sub-plane 420.

The memory device can include two dynamic latch devices 430 and 440. The first dynamic latch device 430 is controllably connected between the first sub-plane 410 and the global bit line 450. The second dynamic latch device 440 is controllably connected between the second sub-plane 420 and the global bit line 450. As shown in FIG. 4, the first dynamic latch device 430 connects the local bit lines (e.g., local bit line 471) of the first sub-plane 410 and the global bit line, while the second dynamic latch device 440 connects the local bit lines (e.g., local bit line 472) of the second sub-plane 420 and the global bit line 450. In some examples, the first and second sub-planes 410 and 420 may share a common set of local bit lines. For example, the local bit line 471 can be shared by the memory cells in the first and second sub-plane that are located on a same column. For simplicity, only a single local bit line is illustrated in each sub-plane; however, it should be understood that each column of memory cells is associated with a local bit line.

A memory device further includes a control logic coupled to the memory plane 400. The control logic may be a system controller 115 and/or local controller 135 of FIG. 1. The control logic is configured to perform one or more data sensing operations (e.g., a random read operation, a program verify operation) of selected memory cells in the first group and the second group of the same memory plane. In some examples, the one or more data sensing operations comprises: causing, at a time point during the one or more data sensing operations, one of the first dynamic latch device 430 or the second dynamic latch device 440, but not both, to communicate data sensed from the first group or the second group, respectively, to the global bit line 450 while storing data sensed from the other one of the first group or the second group in the respective first dynamic latch device 430 or the second dynamic latch device 440.

For example, with reference to FIG. 4, in random read operations, there are two memory cells with one in the top sub-plane 410 (referred as first memory cell), the other in the bottom sub-plane 420 (referred as second memory cell), need to be sensed. If the first memory cell in the top sub-plane 410 is the selected memory cell that undergoes a data sensing operation, the first dynamic latch device 430 is activated to allow communication between the first group of memory cells and the global bit line 450. The page buffer 460 senses the data from the first memory cell through the global bit line 450. Meanwhile, the second dynamic latch device 440 is inactive such that the second group of memory cells cannot communicate with the global bit line 450. However, the second memory cell in the second group of memory cells can be pre-charged and the sensed data can be temporarily stored in the second dynamic latch device 440.

In some examples, the control logic is further configured to cause the page buffer 460 to obtain the data sensed from the other one of the first group or the second group from the respective first dynamic latch device 430 or the second dynamic latch device 440 while the respective first dynamic latch device 430 or the second dynamic latch device 440 is switched to communicate with the global bit line 450.

Continuing with the example discussed above, after the data sensing operation performed on the first memory cell is finished, the first dynamic latch device 430 is deactivated to prevent communication between the first group of memory cells with the global bit line 450, and the second dynamic latch device 440 is activated to allow communication between the second group of memory cells and the global bit line 450. Since the sensed data associated with the second memory cell is already stored in the second dynamic latch device 440, the page buffer 460 can obtain the data sensed from the second dynamic latch device 440 directly instead of from the second memory cell. The read operations thus can have a reduced time delay and an improved reading performance.

In some examples, still referring to FIG. 4, the memory plane further comprises a first set of local word lines 481 and a second set of local word lines 482. For simplicity, only a single local word line is illustrated in each sub-plane; however, it should be understood that each row of memory cells is associated with a local word line. Each local word line in the first set of local word lines 481 is coupled to a corresponding row of the first group of memory cells in the first sub-plane 410. Each local word line in the second set of local word lines 482 is coupled to a corresponding row of the second group of memory cells in the second sub-plane 420.

The memory device further comprises a first global word line 491 and a second global word line 492. The first global word line 491 is coupled to the first set of local word lines 481. The second global word line 492 is coupled to the second set of local word lines 482. The control logic is further configured to cause the first or second set of local word lines 481 or 482 to raise to a set of word line voltages via a respective first or second global word line 491 or 492.

Since the first sub-plane 410 (e.g., top sub-plane) and the second sub-plane 420 (e.g., bottom sub-plane) are coupled to different sets of word lines, data stored in the two sub-planes can be sensed independently. For example, during data sensing operations, a specific set of voltages can be applied to the first set of local word lines 481 to sense data stored in the first memory cell, while a different set of voltages is applied to the second set of local word lines 482 to allow the data sensed from the second memory cell to be stored in the second dynamic latch device 440. This configuration enables independent operation of the first and second sub-planes, preventing interference between them.

As illustrated in FIG. 4, the first and second dynamic latch devices 430 and 440 are represented by two blocks. The two devices act as a bridge between the memory cells on the first sub-plane 410 and the global bit line 450 or between the memory cells on the second sub-plane 420 and the global bit line 450. The second dynamic latch device 440 may have a similar structure and function as the first dynamic latch device 430. Data communication between the respective sub-plane and the global bit line 450 is facilitated through either the first or second dynamic latch device 430 or 440. For example, if the selected memory cell is located on the first sub-plane 410, the page buffer 440 can then be controlled (e.g., by the control logic) to sense the selected memory cells and retrieves the sensed data through the first dynamic latch device 430; if the selected memory cell is located on the second sub-plane 420, the page buffer 440 can then be controlled (e.g., by the control logic) to sense the selected memory cells and retrieves the sensed data through the second dynamic latch device 440.

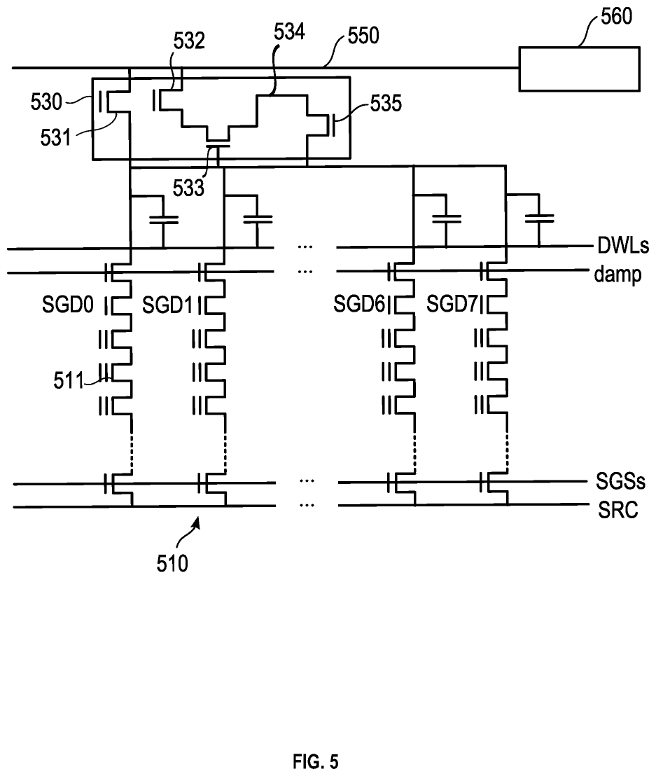

The operation of the dynamic latch device is described next. FIG. 5 is an illustrative schematic of the first sub-plane 510 and the first dynamic latch device 530 in a memory device in accordance with examples as disclosed herein. The first sub-plane 510 could be the same as or similar to the top sub-plane 410 in FIG. 4 and the first dynamic latch device 530 could be the same as or similar to the first dynamic latch device 430 in FIG. 4. For simplicity, only 7 sub-blocks (or memory strings) and one dynamic latch device 530 are shown for the first sub-plane in FIG. 5. It is understood that more sub-blocks or blocks can be included in each sub-plane and more dynamic latch devices can be included in each sub-plane. The first dynamic latch device 530 is represented by dashed block. In some examples, the first dynamic latch device 530 further comprises a storage device 533, a write transistor group 531 and a read transistor group 532. The write transistor group 531 (denoted as WSG) comprises one or more write transistors connected between the global bit line 550 and the storage device 533. The read transistor group 532 (denoted as RSG) comprises one or more read transistors connected between the storage device 533 and the global bit line 550. The storage device 533 (e.g., a TFT) is connected between one or more read transistors and a source line 534. The storage device 533 is controllable to store the sensed data at a sense memory node. During a program operation, the respective dynamic latch device is activated by activating its write transistor group 531 to program the selected memory cell. During the program operation, the read transistor group 532 may be turned off or deactivated. When a data sensing operation (e.g., a read operation) is in progress, the respective dynamic latch device is activated by activating its read transistor group 532, allowing the page buffer 560 to obtain data from the selected memory cell. During a data sensing operation (e.g., a read operation), the write transistor group 531 may be deactivated or turned off. The sensed data can be stored temporarily on the sense memory node (e.g., the gate node of storage device 533), and then be transferred to the global bit line 550 under the control logic. The second dynamic latch device may have a similar configuration to the first dynamic latch device 530, thus the detailed description of it is omitted.

In some examples, the first dynamic latch device or the second dynamic latch device further comprises a source select gate. Still referring to FIG. 5, the source select gate (denoted as SSG) 535 is coupled to the source line 534 and configured to connect the source line 534 to the selected memory cells prior to data communication by the respective dynamic latch device to the global bit line 550, thereby pre-charging the selected memory cells before a data sensing operation. For example, if the source select gate 535 in the first dynamic latch device 530 is tuned on, the selected memory cell (e.g., a first memory cell 511 in one of the subblocks of device 510) is pre-charged by the source line 534. Even if the first dynamic latch device 530 remains inactive at this stage, the potential of the pillar contact and the channel potential of the first memory cell 511 begin to develop. The sense memory node potential of the first dynamic latch device 530 also starts to change, and the sensed data, which is reflected by variations in the sense memory node potential, is stored in the storage device 533 of the first dynamic latch device 530. When the first dynamic latch device 530 is active and communicates with the global bit line 550, the global bit line 550 is modulated by the sense memory node potential. Since the sense memory node potential of the first dynamic latch device 530 has already been modulated depending on Vth of the selected memory cell after the pre-charge phase, there is no need to wait for the pillar contact potential or the channel potential of the first memory cell 511 to develop. As a result, the pre-charge phase reduces read latency and enhances read speed.

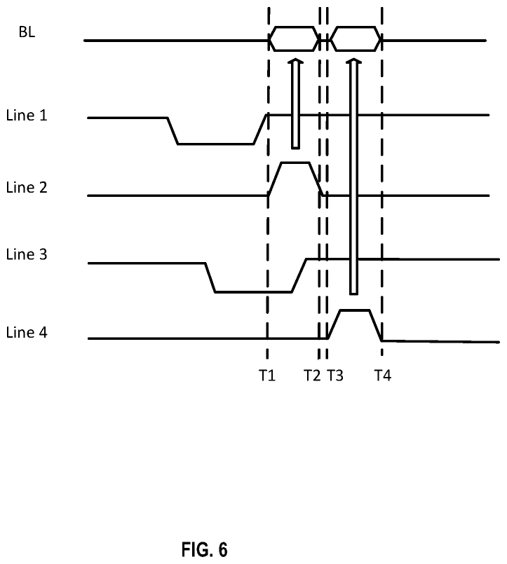

A detailed description of a data sensing operation is provided with reference to FIG. 6. FIG. 6 illustrates the temporal variations of multiple voltages applied to a memory plane. The memory plane which includes a first sub-plane and the second sub-plane may be the memory plane 400 shown in FIG. 4 and have a first sub-plane 510 shown in FIG. 5. In FIG. 6, the first line in the diagram corresponds to the global bit line (denoted as BL). The waveform line 1 corresponds to the voltage signal applied to the local word line connected to a selected memory cell in the first sub-plane (e.g., the first memory cell 511). Waveform line 2 corresponds to the voltage signal applied to the read transistor group in the first dynamic latch device. Waveform line 3 corresponds to the voltage signal applied to the local word line connected to another memory cell requiring later sensing in the second sub-plane (e.g., a second memory cell in one subblock of the bottom sub-plane). Waveform line 4 corresponds to the voltage signal applied to the read transistor group in the second dynamic latch device.

Prior to sensing the first memory cell 511 (e.g., before time point T1 in FIG. 6), a predetermined word line voltage is applied to the control gate of the first memory cell 511 via a corresponding local word line. Subsequently, a pre-charge voltage is applied by the source line to the first memory cell 511 via the corresponding local bit line. At this stage, the selected memory cell (e.g., the first memory cell 511) is pre-charged. Although the first dynamic latch device remains inactive (e.g., deactivating its RSG by applying a low-level voltage), the potential of the pillar contact and the channel potential of the first memory cell 511 begin to develop. The sense memory node potential of the first dynamic latch device also starts to change, and the sensed data, which is reflected by variations in the sense memory node potential, is stored in the storage device of the first dynamic latch device.

When the first memory cell 511 is being sensed (e.g., between time points T1-T2), the first dynamic latch device is activated (e.g., by applying a high-level voltage to activate its RSG) and communication between the first sub-plane and the global bit line is established. The potential level of the global bit line is modulated according to the data stored in the sense memory node of the first dynamic latch device. In this manner, the page buffer could obtain the sensed data from the first memory cell 511. The shorter arrow shown in FIG. 6 represents the data flowing from the first dynamic latch device to the global bit line.

Before or during the first memory cell 511 is being sensed (e.g., before time point T2), a certain word line voltage can be applied to the control gate of the second memory cell through a corresponding local word line. Then, a pre-charge voltage can be applied by the source line in the second dynamic latch device to the second memory cell through the corresponding local bit line. At this point, the selected memory cell (e.g., the second memory cell) has been pre-charged. Even though the second dynamic latch device is not activated (e.g., by applying a low-level voltage to its RSG), the potential of pillar contact and channel potential of the first memory cell 511 starts to develop. The potential of the sense memory node of the second dynamic latch device also starts to change and the sensed data which is reflected by the potential changes of sense memory node can be stored in the storage device of the second dynamic latch device.

When the second memory cell is being sensed (e.g., between time points T3-T4), the second dynamic latch device is activated (e.g., by applying a high-level voltage to activate its RSG) and communication between the second sub-plane and the global bit line is established. The potential level of the global bit line is modulated according to the data stored in the sense memory node of the second dynamic latch device. In this manner, the page buffer could obtain the sensed data from the second memory cell. The longer arrow shown in FIG. 6 represents the data flowing from the second dynamic latch device to the global bit line.

After that, the first and second dynamic latch devices are activated alternatively until all memory cells need to be read are sensed. When the first dynamic latch device is activated and connected to the global bit line, the page buffer could obtain data sensed from the memory cells in the first sub-plane; and when the second dynamic latch device is activated and connected to the global bit line, the page buffer could obtain data sensed from the memory cells in the second sub-plane. This process can be performed for sensing memory cells at different logical states (e.g., applying different word line voltages for sensing different logical states corresponding to different logical pages).

In some examples, the sensed data represents one or more logical states of one or more selected memory cells. During one or more data sensing operations, the control logic is further configured to cause a plurality of word line voltages to be applied to the one or more selected memory cells to obtain the data.

For example, memory array forms a part of a TLC memory device. As described above, a TLC device has 8 logic levels (denoted as L0-L7). The description below uses TLC device as an example. It is understood that the technologies described can be applied to other types of memory devices like a QLC device. For other types of memory devices, there might be more or less logic levels. TLC memory device supports three pages (e.g., Extra, Upper and Lower). These three pages are also denoted as XP, UP, and LP. Each logical level and its corresponding three page states are shown in Table 1.

TABLE 1
Each logical level and its
corresponding three page states

| | LC | L1 | L2 | L3 | L4 | L5 | L6 | L7 |
|---|---|---|---|---|---|---|---|---|
| Extra | 1 | 1 | 1 | 0 | 0 | 0 | 0 | 1 |
| Upper | 1 | 1 | 0 | 0 | 1 | 1 | 0 | 0 |
| Lower | 1 | 0 | 0 | 0 | 0 | 1 | 1 | 1 |

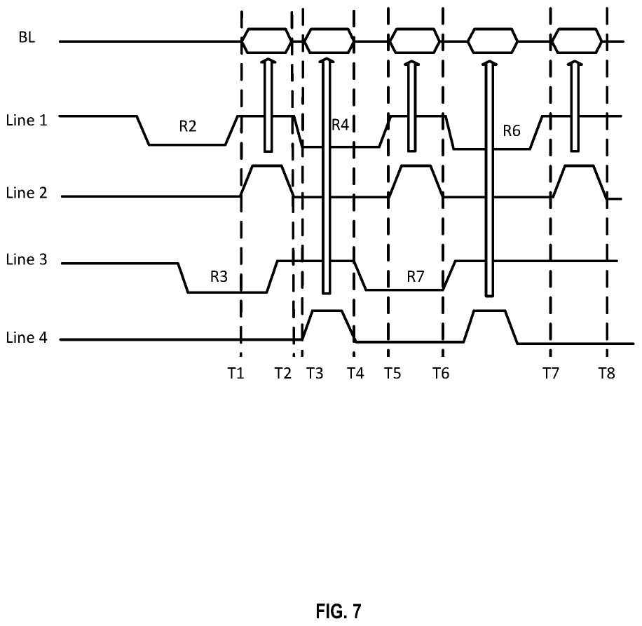

Another process of a data sensing operation performed on the TLC memory device will be described in detail along with FIG. 7. FIG. 7 illustrates the variations of multiple voltages applied to a memory plane over time. The memory plane described here may be in a TLC memory device. Similar to FIG. 6, in FIG. 7, the first line in the diagram corresponds to the global bit line. Waveform line 1 corresponds to the voltage signal applied to the local word line connected to a selected memory cell in the first sub-plane (e.g., the first memory cell 511). Waveform line 2 corresponds to the voltage signal applied to the read transistor group in the first dynamic latch device. Waveform line 3 corresponds to the voltage signal applied to the local word line connected to another memory cell requiring later sensing in the second sub-plane (e.g., the second memory cell). Waveform line 4 corresponds to the voltage signal applied to the read transistor group in the second dynamic latch device.

In the example of FIG. 7, selected memory cells in the first or second sub-plane require 7 data sensing operations to determine all three logical page states of the selected memory cells. In each data sensing operation, the selected memory cells are applied to a different word line voltage (e.g., R1-R7) to determine its logical states.

Referring to FIG. 7, prior to time point T1, the selected memory cell in the first sub-plane (e.g., the first memory cell 511) are applied with R2 to determine their upper page states (e.g., 0 or 1). Referring to the Table 1, since the upper page level of L0 and L1 are “1” and the upper page level of L2 and L3 are “0”, applying voltage R2 can distinguish L0, L1 from L2, L3. As discussed above, the selected memory cells can be pre-charged before the corresponding sub-plane communicates with the global bit line. The potential of pillar contact and channel potential of the selected memory cell starts to develop. The sensed data (e.g., upper page states of the selected memory cell) can be stored in the storage device of the first dynamic latch device.

During time points from T1 to T2, the first dynamic latch device is activated (e.g., by applying a high-level voltage to activate its RSG), and the first sub-plane can communicate with the global bit line. The potential level of the global bit line is modulated according to data stored in the storage device of the first dynamic latch device. The page buffer then obtains the sensed data indicating whether the selected memory cell is in L0, L1 or L2, L3.

During time points from T3 to T5, the first dynamic latch device is inactive (e.g., by applying a low-level voltage to deactivate its RSG). The selected memory cell in the first sub-plane (e.g., the first memory cell 511) is applied with word line voltage R4 to further determine their upper page states (e.g., 0 or 1). Referring to the Table 1, the upper page level of L2 and L3 are “0” and the upper page level of L4 and L5 are “1”, applying R4 voltage can distinguish L2, L3 from L4, L5.

Likewise, during time points T5 to T6, the first dynamic latch device is activated, and the first sub-plane can communicate with the global bit line again. The potential level of the global bit line is modulated according to data stored in the storage device of the first dynamic latch device. The page buffer then obtains the sensed data indicating whether the first memory cell 511 is in L2, L3 or L4, L5. During time points from T6 to T7, word line voltage R6 is applied to first memory cell 511s. The page buffer then (e.g., during T7 to T8) obtains the sensed data indicating whether the selected memory cell is in L4, L5 or L6, L7.

After that, word line voltages R3 and R7 (not shown in FIG. 7) can be applied to the first memory cell 511 for determining their extra page stages; and then word line voltages R1 and R5 (not shown in FIG. 7) can be applied to the first memory cell 511 for determining their lower page stages. In some examples, after all 7 data sensing operations, which means 7 different word line voltages are applied to the first memory cell 511s in the first sub-plane sequentially. The page buffer could determine the exact level (e.g., L0-L7) of the first memory cell 511. In other examples, not all 7 word line voltages are required to determine the logical state of the first memory cell 511s.

When the selected memory cells in the first sub-plane 410 (e.g., the first memory cell 511) undergoes data sensing operations, one or more selected memory cells in the second sub-plane (e.g., the second memory cell) can be sensed too. As shown in FIG. 7, before time point T3, the second memory cell in the second sub-plane can be applied with word line voltage R3 to determine their extra page stages. During time points from T3 to T4, the first dynamic latch device is disconnected to the global bit line, and the second dynamic latch device may exploit this period to establish communication between the second sub-plane and the global bit line. The page buffer then can obtain the sensed data from the second memory cell in the second sub-plane indicating the extra page stages of the selected memory cells. Similarly, in some examples, after all 7 data sensing operations, which means 7 different word line voltages are applied to the second memory cell in the second sub-plane sequentially. The page buffer could determine the exact level (e.g., L0-L7) of the second memory cell. Although FIG. 7 illustrates the application of seven different word line voltages to the selected memory cell in a specific order, it should be understood that these voltages may be applied in any order and not all seven different word line voltages may be required in some examples

In the example of a TLC memory device, seven different word line voltages can be applied to the selected memory cells. However, for other types of memory devices, the number of word line voltages applied varies depending on the number of logic levels, with some memory devices requiring more or fewer word line voltages accordingly.

When the selected memory cell is applied with a word line voltage as described above, the control logic is further configured to cause the local word line connected to the selected memory cell to rise to a target word line voltage while causing local word lines connected to unselected memory cells to rise to a pass voltage. In this manner, only the selected memory cell is activated while keeping the other memory cells inactive. The page buffer can then read the sensed data exclusively from the selected memory cell.

In summary, the control logic can exploit the time interval between two consecutive communications of the first sub-plane to establish the communication of the second sub-plane, and vice versa. In this way, the memory cells in the first and second sub-planes can be sensed during the same period, thus improving the efficiency of data sensing operations.

In some examples, the memory plane described is a first memory plane. The memory device further comprises one or more additional memory planes. The control logic is configured to perform additional data sensing operations with respect to the one or more additional memory planes in parallel with the one or more data sensing operations performed with respect to the first memory plane.

For example, the memory system may include four memory planes, such as a first memory plane, a second memory plane, a third memory plane, and a fourth memory plane. The control logic is configured to perform data sensing operations on each memory plane asynchronously, allowing independent read operations across different planes to improve overall performance.

Specifically, during a read operation, the control logic may initiate a data sensing operation on the first memory plane while performing additional asynchronous data sensing operations on the second, third, and fourth memory planes. To further enhance read efficiency, the memory device may employ an iWLx4 Read mechanism, where each independent Word Line (iWL) enables the simultaneous retrieval of four bits per read operation.

For instance, while the first memory plane completes a read operation, the second memory plane can begin a separate read operation without waiting, followed by similar independent read operations on the third and fourth memory planes.

By utilizing the iWLx4 Read scheme, each memory plane can execute independent read operations in parallel, significantly reducing latency and increasing throughput. This asynchronous multi-plane read approach is particularly beneficial in high-density memory architectures, enabling faster data access, improved power efficiency, and optimized memory bandwidth utilization. Although this example illustrates a memory device with four memory planes, it should be understood that a memory device may include more or fewer memory planes, provided it is capable of performing random read operations.

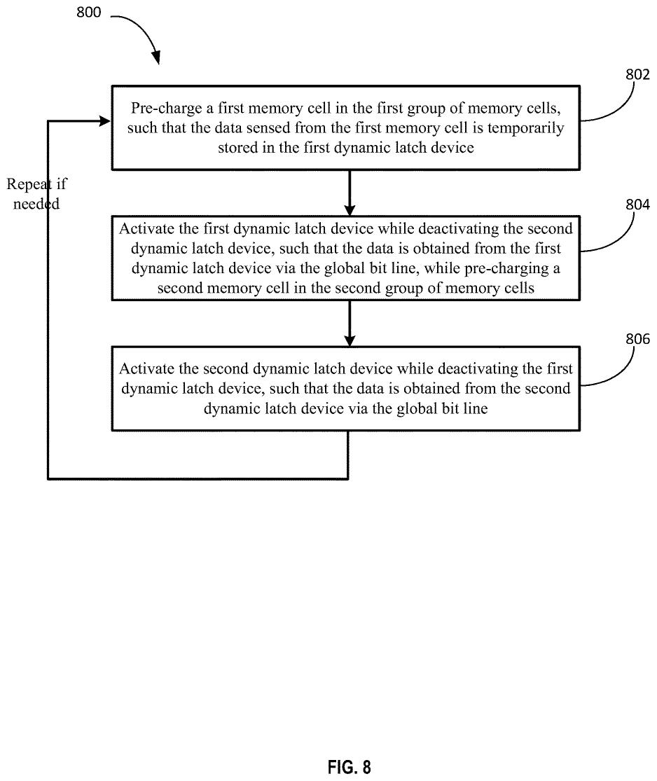

FIG. 8 is a flowchart showing a method 800 performed by the memory device in accordance with examples as disclosed herein. The memory device includes a memory plane divided into a first sub-plane and a second sub-plane, a global bit line, a first dynamic latch device and a second dynamic latch device. The memory plane might be the same as or similar to the memory plane 400 shown in FIG. 4. The first sub-plane, the second sub-plane and the global bit line may be similar to the first sub-plane 410, the second sub-plane 420 and the global bit line 450 illustrated in FIG. 4. The first dynamic latch device and the second dynamic latch device may be similar to the dynamic latch device 530 illustrated in FIG. 5. The first sub-plane comprises a first group of memory cells. The second sub-plane comprises a second group of memory cells. The first dynamic latch device is controllably connected between the first group of memory cells and the global bit line. The second dynamic latch device is controllably connected between the second group of memory cells and the global bit line. The blocks in FIG. 8 can be performed by the control logic, other components of the memory device (e.g., sense amplifier, page buffer, etc.), or a combination thereof.

Referring to FIG. 8, in block 802, the control logic pre-charges a first memory cell in the first group of memory cells, such that the data sensed from the first memory cell is temporarily stored in the first dynamic latch device.

For example, prior to sensing the first memory cell, a predetermined word line voltage is applied to the control gate of the first memory cell via a corresponding local word line. Subsequently, a pre-charge voltage is applied by a source line to the first memory cell via the corresponding local bit line. At this stage, the selected memory cell (e.g., the first memory cell) is pre-charged. Although the first dynamic latch device may remain inactive at this stage, the potential of the pillar contact and the channel potential of the first memory cell begin to develop. A sense memory node potential of the first dynamic latch device also starts to change, and the sensed data, which is reflected by variations in the sense memory node potential, is stored in the storage device of the first dynamic latch device.

In block 804, the control logic activates the first dynamic latch device while deactivating the second dynamic latch device, such that the data is obtained from the first dynamic latch device via the global bit line, while pre-charging a second memory cell in the second group of memory cells.

For example, if the selected memory cell in the first sub-plane (e.g., the first memory cell) undergoes a data sensing operation, the first dynamic latch device will be activated to allow communication between the selected memory cells and the global bit line. The page buffer then senses the data from the selected memory cells through the global bit line. Meanwhile, the second dynamic latch device is inactive such that the memory cells in the bottom sub-plane cannot communicate with the global bit line. However, the memory cell in the second sub-plane needs to be sensed later can be pre-charged and sensed data can be temporarily stored in the second dynamic latch device. Once the second dynamic latch device is activated, the page buffer can obtain the sensed data from the second dynamic latch device.

In block 806, the control logic activates the second dynamic latch device while deactivating the first dynamic latch device, such that the data is obtained from the second dynamic latch device via the global bit line. The method further comprises repeating the process until all memory cells need to be read have been sensed.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller or control logic, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller or control logic isolates two components, the controller or control logic affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

### ADDITIONAL EXAMPLES

Example 1: A memory device comprising: a memory plane comprising: a first sub-plane comprising a first group of memory cells; and a second sub-plane comprising a second group of memory cells; a global bit line coupled to both the first sub-plane and the second sub-plane; a first dynamic latch device controllably connected between the first group of memory cells and the global bit line; a second dynamic latch device controllably connected between the second group of memory cells and the global bit line; and control logic configured to perform one or more data sensing operations of selected memory cells in the first group and the second group of the same memory plane, the one or more data sensing operations comprising: causing, at a time point during the one or more data sensing operations, one of the first dynamic latch device or the second dynamic latch device, but not both, to communicate data sensed from the first group or the second group, respectively, to the global bit line while storing data sensed from the other one of the first group or the second group in the respective first dynamic latch device or the second dynamic latch device.

Example 2: The memory device of example 1, further comprising a page buffer coupled to the global bit line, wherein the control logic is further configured to perform: causing the page buffer to obtain the data sensed from the other one of the first group or the second group from the respective first dynamic latch device or the second dynamic latch device while the respective first dynamic latch device or the second dynamic latch device is switched to communicate with the global bit line.

Example 3: The memory device of example 2, wherein the first dynamic latch device or the second dynamic latch device comprises: a storage device; a write transistor group comprising one or more write transistors connected between the global bit line and the storage device; and a read transistor group comprising one or more read transistors connected between the storage device and the global bit line; wherein: the storage device is connected between the one or more read transistors and a source line, the storage device being controllable to store data at a sense memory node coupled to the one or more write transistors.

Example 4: The memory device of example 3, wherein the storage device comprises a sense amplification transistor controlled by the control logic to perform sense amplification during the one or more data sensing operations.

Example 5: The memory device of any of examples 3-4, wherein the control logic is further configured to perform: causing the first dynamic latch device or the second dynamic latch device to communicate data to the global bit line by activating the read transistor group of the first dynamic latch device or the second dynamic latch device.

Example 6: The memory device of any of examples 3-5, wherein the data represent one or more logical page states of one or more selected memory cells, wherein during the one or more data sensing operations, the control logic is further configured to cause a plurality of word line voltages to be applied to the one or more selected memory cells to obtain the data.

Example 7: The memory device of any of examples 3-6, wherein the first dynamic latch device or the second dynamic latch device further comprises: a source select gate coupled to the source line and configured to connect the source line to the selected memory cells prior to data communication by the respective dynamic latch device to the global bit line, thereby pre-charging the selected memory cells before a data sensing operation.

Example 8: The memory device of any of examples 1-7, wherein the memory plane further comprises: a first set of local word lines, each coupled to a corresponding row of the first group of memory cells in the first sub-plane; a second set of local word lines, each coupled to a corresponding row of the second group of memory cells in the second sub-plane; wherein the memory device further comprises: a first global word line coupled to the first set of local word lines; and a second global word line coupled to the second set of local word lines, wherein the control logic is further configured to perform: causing the first or second set of local word lines to raise to a set of word line voltages via a respective first or second global word line.

Example 9: The memory device of example 8, wherein the control logic is further configured to perform: causing a local word line connected to a selected memory cell to rise to a target word line voltage; and causing local word lines connected to unselected memory cells to rise to a pass voltage.

Example 10: The memory device of any of examples 1-9, wherein the first or second group of memory cells comprises tri-level or quad-level memory cells.

Example 11: The memory device of any of examples 1-9, wherein the memory plane is a first memory plane, further comprising: one or more additional memory planes, wherein the control logic is configured to perform additional data sensing operations with respect to the one or more additional memory planes in parallel with the one or more data sensing operations performed with respect to the first memory plane.

Example 12: A method for performing a data sensing operation of a memory device comprising a memory plane having a first sub-plane and a second sub-plane, a global bit line, a first dynamic latch device and a second dynamic latch device, wherein the first sub-plane comprises a first group of memory cells; the second sub-plane comprises a second group of memory cells; the first dynamic latch device is controllably connected between the first group of memory cells and the global bit line; and the second dynamic latch device is controllably connected between the second group of memory cells and the global bit line, the method comprising: pre-charging a first memory cell in the first group of memory cells, such that the data sensed from the first memory cell is temporarily stored in the first dynamic latch device; activating the first dynamic latch device while deactivating the second dynamic latch device, such that the data is obtained from the first dynamic latch device via the global bit line, while pre-charging a second memory cell in the second group of memory cells; and activating the second dynamic latch device while deactivating the first dynamic latch device, such that the data is obtained from the second dynamic latch device via the global bit line.

What is claimed is:

1. A memory device comprising:
a memory plane comprising:
a first sub-plane comprising a first group of memory cells; and
a second sub-plane comprising a second group of memory cells;
a global bit line coupled to both the first sub-plane and the second sub-plane;
a first dynamic latch device controllably connected between the first group of memory cells and the global bit line;
a second dynamic latch device controllably connected between the second group of memory cells and the global bit line; and
control logic configured to perform one or more data sensing operations of selected memory cells in the first group and the second group of the same memory plane, the one or more data sensing operations comprising:
causing, at a time point during the one or more data sensing operations, one of the first dynamic latch device or the second dynamic latch device, but not both, to communicate data sensed from the first group or the second group, respectively, to the global bit line while storing data sensed from the other one of the first group or the second group in the respective first dynamic latch device or the second dynamic latch device.

2. The memory device of claim 1, further comprising a page buffer coupled to the global bit line, wherein the control logic is further configured to perform:
causing the page buffer to obtain the data sensed from the other one of the first group or the second group from the respective first dynamic latch device or the second dynamic latch device while the respective first dynamic latch device or the second dynamic latch device is switched to communicate with the global bit line.

3. The memory device of claim 2, wherein the first dynamic latch device or the second dynamic latch device comprises:
a storage device;
a write transistor group comprising one or more write transistors connected between the global bit line and the storage device; and
a read transistor group comprising one or more read transistors connected between the storage device and the global bit line; wherein:
the storage device is connected between the one or more read transistors and a source line, the storage device being controllable to store data at a sense memory node coupled to the one or more write transistors.

4. The memory device of claim 3, wherein the storage device comprises a sense amplification transistor controlled by the control logic to perform sense amplification during the one or more data sensing operations.

5. The memory device of claim 3, wherein the control logic is further configured to perform:
causing the first dynamic latch device or the second dynamic latch device to communicate data to the global bit line by activating the read transistor group of the first dynamic latch device or the second dynamic latch device.

6. The memory device of claim 3, wherein the data represent one or more logical page states of one or more selected memory cells, wherein during the one or more data sensing operations, the control logic is further configured to cause a plurality of word line voltages to be applied to the one or more selected memory cells to obtain the data.

7. The memory device of claim 3, wherein the first dynamic latch device or the second dynamic latch device further comprises:
a source select gate coupled to the source line and configured to connect the source line to the selected memory cells prior to data communication by the respective dynamic latch device to the global bit line, thereby pre-charging the selected memory cells before a data sensing operation.

8. The memory device of claim 1, wherein the memory plane further comprises:
a first set of local word lines, each coupled to a corresponding row of the first group of memory cells in the first sub-plane;
a second set of local word lines, each coupled to a corresponding row of the second group of memory cells in the second sub-plane;
wherein the memory device further comprises:
a first global word line coupled to the first set of local word lines; and
a second global word line coupled to the second set of local word lines,
wherein the control logic is further configured to perform:
causing the first or second set of local word lines to raise to a set of word line voltages via a respective first or second global word line.

9. The memory device of claim 8, wherein the control logic is further configured to perform:
causing a local word line connected to a selected memory cell to rise to a target word line voltage; and
causing local word lines connected to unselected memory cells to rise to a pass voltage.

10. The memory device of claim 1, wherein the first or second group of memory cells comprises tri-level or quad-level memory cells.

11. The memory device of claim 1, wherein the memory plane is a first memory plane, further comprising:
one or more additional memory planes, wherein the control logic is configured to perform additional data sensing operations with respect to the one or more additional memory planes in parallel with the one or more data sensing operations performed with respect to the first memory plane.

12. A method for performing a data sensing operation of a memory device comprising a memory plane having a first sub-plane and a second sub-plane, a global bit line, a first dynamic latch device and a second dynamic latch device, wherein the first sub-plane comprises a first group of memory cells; the second sub-plane comprises a second group of memory cells; the first dynamic latch device is controllably connected between the first group of memory cells and the global bit line; and the second dynamic latch device is controllably connected between the second group of memory cells and the global bit line, the method comprising:
pre-charging a first memory cell in the first group of memory cells, such that the data sensed from the first memory cell is temporarily stored in the first dynamic latch device;
activating the first dynamic latch device while deactivating the second dynamic latch device, such that the data is obtained from the first dynamic latch device via the global bit line, while pre-charging a second memory cell in the second group of memory cells; and
activating the second dynamic latch device while deactivating the first dynamic latch device, such that the data is obtained from the second dynamic latch device via the global bit line.
